(19) United States
(12) Patent Application Publication
(10) Pub. No.: US 2025/0258036 A1
(43) Pub. Date: Aug. 14, 2025

(54) OPTICAL MODULE AND METHOD FOR MANUFACTURING OPTICAL MODULE

(71) Applicant: SUMITOMO ELECTRIC INDUSTRIES, LTD., Osaka (JP)

(72) Inventors: Satoshi YOSHIMURA, Osaka (JP); Tomoya SAEKI, Osaka (JP); Yuki NAKAMURA, Osaka (JP)

(21) Appl. No.: 19/050,196

(22) Filed: Feb. 11, 2025

(30) Foreign Application Priority Data
Feb. 13, 2024 (JP) 2024-019621

(51) Int. Cl. G01J 1/04; H01S 5/0236

(52) U.S. Cl. CPC G01J 1/0403; H01S 5/0236

(57) ABSTRACT

An optical module includes a base material, an optical semiconductor element, an optical circuit element, a first adhesive, and a second adhesive. The base material has a first surface. The optical semiconductor element has a first optical port and is provided on the first surface. The optical circuit element has a second optical port, which faces the first optical port and is optically coupled to the first optical port, in a side surface thereof. The optical circuit element is disposed alongside the optical semiconductor element on the first surface. The first adhesive mainly includes a UV curable material. The first adhesive fixes the optical semiconductor element to the first surface and has a first thermal conductivity. The second adhesive mainly includes a thermosetting material and has a second thermal conductivity higher than the first thermal conductivity. The second adhesive fixes the optical semiconductor element to the first surface.

### CROSS-REFERENCE

This application claims priority to Japanese Application No. 2024-019621, filed on Feb. 13, 2024, the entire contents of which are incorporated herein by reference.

### TECHNICAL FIELD

The present disclosure relates to an optical module and a method for manufacturing an optical module.

### BACKGROUND

Japanese Unexamined Patent Publication No. 2000-236002 discloses a flip chip connection method. This method includes a first step and a second step. In the first step, a conductive paste is transferred to a bump provided on a semiconductor chip. In the second step, the bump is connected to a conductive pattern on a substrate, and a portion in which the bump is not formed in the semiconductor chip is bonded to the substrate by an adhesive sealing resin.

Japanese Unexamined Patent Publication No. 2006-108238 discloses a light emitting device. The light emitting device includes a semiconductor light emitting element, a conductive member, a conductive paste, and a fixing resin. The conductive paste electrically connects an electrode of the semiconductor light emitting element and the conductive member. The fixing resin covers a lower side surface of the semiconductor light emitting element and a portion in which the conductive paste is not applied in a bottom surface to fix the semiconductor light emitting element to the conductive member.

Japanese Unexamined Patent Publication No. 2017-092389 discloses a semiconductor device. The semiconductor device includes a semiconductor element, a support, sintered silver for bonding the semiconductor element to the support, and a resin for bonding the semiconductor element to the support. The resin is formed in at least a portion of a contour region along a contour of the semiconductor element. Japanese Unexamined Patent Publication No. 2022-522796 discloses a method for controlling a wavelength of an external-cavity tunable laser using silicon photonics.

### SUMMARY

An optical module according to an embodiment of the present disclosure includes a base material, an optical semiconductor element, an optical circuit element, a first adhesive, and a second adhesive. The base material has a first surface. The optical semiconductor element has a first optical port for light incidence, light emission, or light incidence and emission in a side surface thereof and is provided on the first surface. The optical circuit element has a second optical port, which is for light incidence, light emission, or light incidence and emission, faces the first optical port, and is optically coupled to the first optical port, in a side surface thereof. The optical circuit element is disposed alongside the optical semiconductor element on the first surface. The first adhesive mainly includes a UV curable material. The first adhesive is disposed between the optical semiconductor element and the first surface to fix the optical semiconductor element to the first surface. The first adhesive has a first thermal conductivity. The second adhesive mainly includes a thermosetting material and has a second thermal conductivity higher than the first thermal conductivity. The second adhesive is disposed between the optical semiconductor element and the first surface to fix the optical semiconductor element to the first surface.

### BRIEF DESCRIPTION OF THE DRAWINGS

FIG. 1 is a perspective view showing an optical module according to an embodiment of the present disclosure.

FIG. 2 is a cross-sectional view showing the optical module taken along a line II-II of FIG. 1.

FIG. 3 is a flowchart showing a method for manufacturing an optical module according to this embodiment.

FIG. 4 is a cross-sectional view showing an optical module according to a first modification.

FIG. 5 is a plan view showing a base material, a first adhesive, and

a second adhesive.

FIG. 6 is a cross-sectional view showing a second step in a process of manufacturing the optical module.

FIG. 7 is a cross-sectional view showing the second step in the process of manufacturing the optical module.

FIG. 8 is a cross-sectional view showing the second step in the process of manufacturing the optical module.

FIG. 9 is a plan view showing a base material, a first adhesive, and a second adhesive according to a second modification.

FIG. 10 is a cross-sectional view showing an optical module according to a third modification.

FIG. 11 is a perspective view showing an appearance of a carrier according to the third modification.

FIG. 12 is a diagram for explaining issues associated with an optical module.

FIG. 13 is a cross-sectional view showing how a spread portion of the first adhesive is dammed by a step.

FIG. 14 is a perspective view showing an appearance of a carrier as another form of the third modification.

FIG. 15 is a cross-sectional view of an optical module according to a fourth modification.

FIG. 16 is a perspective view showing the appearance of the carrier according to the fourth modification.

FIG. 17 is a cross-sectional view showing how spread of the first adhesive to a second contact surface is prevented.

FIG. 18 is a perspective view showing an appearance of a carrier as another form of the fourth modification.

FIG. 19 is a cross-sectional view of an optical module according to a fifth modification.

### DETAILED DESCRIPTION

In some cases, an optical semiconductor element having an optical port in a side surface thereof is fixed to a base material after optical axis adjustment is performed for an optical circuit element having another optical port in a side surface thereof. It is desirable to fix the optical semiconductor element to the base material using a thermosetting material, such as sintered silver, having a high thermal conductivity in order to dissipate heat from the optical semiconductor element. However, extremely high temperature is required to cure the thermosetting material such as sintered silver. Therefore, it is difficult to cure the thermosetting material while holding the optical semiconductor element, whose optical axis has been adjusted, with a chuck or the like. Further, when the optical semiconductor element is fixed to the base material using a UV curable material, such as a UV curable resin, it is easy to irradiate the UV curable material with ultraviolet light while holding the optical semiconductor element, whose optical axis has been adjusted, with the chuck or the like, and it is possible to easily cure the UV curable material. However, in this case, there is a concern that the dissipation of heat from the optical semiconductor element will be insufficient due to the low thermal conductivity of the UV curable material.

An object of the present disclosure is to provide an optical module and a method for manufacturing an optical module that can fix an optical semiconductor element subjected to optical axis adjustment to a base material using a thermosetting material with high heat dissipation performance while maintaining a position of the optical semiconductor element.

### Description of Embodiment of the Present Disclosure

First, the contents of an embodiment of the present disclosure will be listed and described. [1] An optical module according to an embodiment of the present disclosure includes a base material, an optical semiconductor element, an optical circuit element, a first adhesive, and a second adhesive. The base material has a first surface. The optical semiconductor element has a first optical port for light incidence, light emission, or light incidence and emission in a side surface thereof and is provided on the first surface. The optical circuit element has a second optical port, which is for light incidence, light emission, or light incidence and emission, faces the first optical port, and is optically coupled to the first optical port, in a side surface thereof. The optical circuit element is disposed alongside the optical semiconductor element on the first surface. The first adhesive mainly includes a UV curable material. The first adhesive is disposed between the optical semiconductor element and the first surface to fix the optical semiconductor element to the first surface. The first adhesive has a first thermal conductivity. The second adhesive mainly includes a thermosetting material and has a second thermal conductivity higher than the first thermal conductivity. The second adhesive is disposed between the optical semiconductor element and the first surface to fix the optical semiconductor element to the first surface.

In the optical module according to [1], the optical semiconductor element is fixed to the first surface of the base material by the first adhesive and the second adhesive. The first adhesive mainly includes the UV curable material. The second adhesive has the second thermal conductivity higher than the first thermal conductivity of the first adhesive and mainly includes the thermosetting material. When this optical module is manufactured, irradiation with ultraviolet light can be performed while the position of the optical semiconductor element subjected to optical axis adjustment is maintained by a chuck or the like to cure the first adhesive. Then, the second adhesive can be cured by heating in a state in which the position of the optical semiconductor element subjected to the optical axis adjustment is maintained by the first adhesive. Therefore, according to the optical module of [1], it is possible to fix the optical semiconductor element to the base material using the thermosetting material with high heat dissipation performance while maintaining the position of the optical semiconductor element subjected to the optical axis adjustment.
[2] In the optical module according to [1], the optical semiconductor element may include: an optical semiconductor chip having the first optical port; and a carrier on which the optical semiconductor chip mounted and fixed to the first surface by the first adhesive and the second adhesive. In this case, even when the thickness of the optical semiconductor chip is smaller than the thickness of the optical circuit element, the height of the first optical port can be matched with the height of the second optical port.
[3] In the optical module according to [1] or [2], the UV curable material may be a UV curable resin. In this case, it is possible to easily fix the optical semiconductor element to the base material.
[4] In the optical module according to any one of [1] to [3], the thermosetting material may be sintered silver. Since the sintered silver has an extremely high thermal conductivity, in this case, it is possible to efficiently transfer heat from the optical semiconductor element to the base material.
[5] In the optical module according to any one of [1] to [3], the thermosetting material may be epoxy-containing sintered silver. When the second adhesive includes the epoxy-containing sintered silver, it is possible to suppress shrinkage of the second adhesive during sintering, and the second adhesive can be less likely to peel from the optical semiconductor element.
[6] In the optical module according to any one of [1] to [5], the first adhesive and the second adhesive may be spaced apart from each other on the first surface. In this case, the mixing of the first adhesive and the second adhesive before curing is avoided. Therefore, it is possible to prevent the curing of the first adhesive from being hindered by the second adhesive.
[7] In the optical module according to any one of [1] to [6], the base material may have a recessed portion formed between the first adhesive and the second adhesive when viewed from a normal direction to the first surface. There is a variation in the height from a bottom surface of the optical semiconductor element to the first optical port due to manufacturing errors. Since the height position of the first optical port is determined by the height position of the second optical port of the optical circuit element, the variation in the height from the bottom surface of the optical semiconductor element to the first optical port is absorbed by the thickness of the first adhesive and the second adhesive. When the thickness of the first adhesive and the second adhesive is small, the first adhesive and the second adhesive spread in a lateral direction (a direction along the first surface) and approach each other. Since the base material has the recessed portion formed between the first adhesive and the second adhesive, the first adhesive and the second adhesive that have spread in the direction in which the adhesives approach each other can be dropped into the recessed portion. Therefore, the mixing of the first adhesive and the second adhesive on the first surface before curing is avoided. As a result, it is possible to prevent the curing of the first adhesive on the first surface from being hindered by the second adhesive.
[8] The optical module according to any one of [1] to [7] may further include a third adhesive that mainly includes a UV curable material having a higher curing speed than the UV curable material of the first adhesive and is disposed between the first optical port and the second optical port. In this case, the third adhesive is cured faster than the first adhesive when irradiation with ultraviolet light is performed. Therefore, it is possible to more firmly maintain the optically coupled state between the first optical port and the second optical port after the optical axis adjustment.
[9] In the optical module according to any one of [1] to [8], a contact area between the second adhesive and the optical semiconductor element may be larger than a contact area between the first adhesive and the optical semiconductor element. In this case, it is possible to more efficiently transfer heat from the optical semiconductor element to the base material.
[10] In the optical module according to any one of [1] to [9], the first adhesive may be provided on a plurality of regions, between which the second adhesive is interposed, on the first surface. In this case, when the second adhesive is cured by heating, it is possible to more stably maintain the position of the first optical port after the optical axis adjustment.
[11] In the optical module according to [10], the plurality of regions may be disposed so as to be line-symmetric with respect to an axis line along the first surface. In this case, it is possible to more stably maintain the position of the first optical port after the optical axis adjustment.
[12] In the optical module according to any one of [1] to [11], the optical semiconductor element may have a bottom surface facing the first surface. The first adhesive and the second adhesive may be spaced apart from each other on the bottom surface of the optical semiconductor element. In this case, the mixing of the first adhesive and the second adhesive before curing is avoided. Therefore, it is possible to prevent the curing of the first adhesive from being hindered by the second adhesive.
[13] In the optical module according to any one of [2] to [12], the carrier may have a bottom surface facing the first surface. The bottom surface may include a first contact surface that the first adhesive contacts and a second contact surface that the second adhesive contacts. The distance between the second contact surface and the first surface may be smaller than the distance between the first contact surface and the first surface. In this case, even if the first adhesive spreads along the bottom surface of the carrier before curing, the spread portion of the first adhesive is dammed by the step between the first contact surface and the second contact surface to prevent the first adhesive from spreading to the second contact surface. Therefore, according to the optical module of [13], it is possible to avoid the mixing of the first adhesive and the second adhesive on or near the bottom surface of the carrier, and to prevent the curing of the first adhesive on or near the bottom surface of the carrier from being hindered by the second adhesive. Furthermore, it is possible to prevent the first adhesive from entering between the second adhesive and the bottom surface of the carrier to increase the area of the second contact surface. Therefore, heat dissipation can be improved.
[14] In the optical module according to [13], the bottom surface of the carrier may further include a third contact surface that the first adhesive contacts. As viewed from the normal direction of the bottom surface of the carrier, the first contact surface may be positioned between the second contact surface and the third contact surface. The distance between the third contact surface and the first surface may be smaller than the distance between the first contact surface and the first surface. In this case, the portion of the first adhesive located on the side surface of the carrier and the portion of the first adhesive located on the first contact surface sandwich a part of the carrier, that is, the part of the carrier between the side surface and the first contact surface, from both sides. This enhances the fixation strength between the carrier and the substrate.
[15] In the optical module according to [13], the bottom surface of the carrier may further include a third contact surface that the first adhesive contacts. As viewed from the normal direction of the bottom surface of the carrier, the first contact surface may be positioned between the second contact surface and the third contact surface. The distance between the third contact surface and the first surface may be larger than the distance between the first contact surface and the first surface. In this case, the spread portion of the first adhesive before curing is further dammed by the step between the first contact surface and the third contact surface. Therefore, the first adhesive is more effectively prevented from spreading to the second contact surface.
[16] A method for manufacturing an optical module according to another embodiment of the present disclosure includes disposing, disposing, curing a first adhesive, and curing a second adhesive. In the first disposing, an optical circuit element having a second optical port for light incidence, light emission, or light incidence and emission in a side surface thereof, the first adhesive mainly including a UV curing material and having a first thermal conductivity, and the second adhesive that mainly includes a thermosetting material and has a second thermal conductivity higher than the first thermal conductivity are disposed on a first surface of a base material. In the second disposing, a position of an optical semiconductor element having a first optical port for light incidence, light emission, or light incidence and emission in a side surface thereof is disposed. During the second disposing, a position of the optical semiconductor element is adjusted such that the first optical port is optically coupled to the second optical port while the optical semiconductor element is brought into contact with the first adhesive and the second adhesive. Such adjustment may be performed by an active alignment method or a passive alignment method. In the curing the first adhesive, the first adhesive is cured using irradiation with ultraviolet light while the optical semiconductor element is maintained at a position adjusted for optical coupling. In the curing the second adhesive, the second adhesive is cured by heating in a state in which the first adhesive is already cured.

In the manufacturing method according to [16], the optical semiconductor element is fixed to the first surface of the base material by the first adhesive and the second adhesive. The first adhesive mainly includes the UV curable material. The second adhesive has the second thermal conductivity higher than the first thermal conductivity of the first adhesive and mainly includes the thermosetting material. In the curing the first adhesive, irradiation with ultraviolet light can be performed while the position of the optical semiconductor element subjected to optical axis adjustment is maintained by a chuck or the like to cure the first adhesive. Then, In the curing the second adhesive, the second adhesive can be cured by heating in a state in which the position of the optical semiconductor element subjected to the optical axis adjustment is maintained by the first adhesive. Therefore, according to the manufacturing method of [16], it is possible to fix the optical semiconductor element to the base material using the thermosetting material with high heat dissipation performance while maintaining the position of the optical semiconductor element subjected to the optical axis adjustment.

### Details of Embodiment of the Present Disclosure

Specific examples of the present disclosure will be described below with reference to the drawings. The present disclosure is not limited to these examples, but is defined by the scope of the claims. The present disclosure is intended to include all modifications within the meaning and scope equivalent to the scope of the claims. In the description of the drawings, the same elements are denoted by the same reference numerals, and redundant description will be omitted.

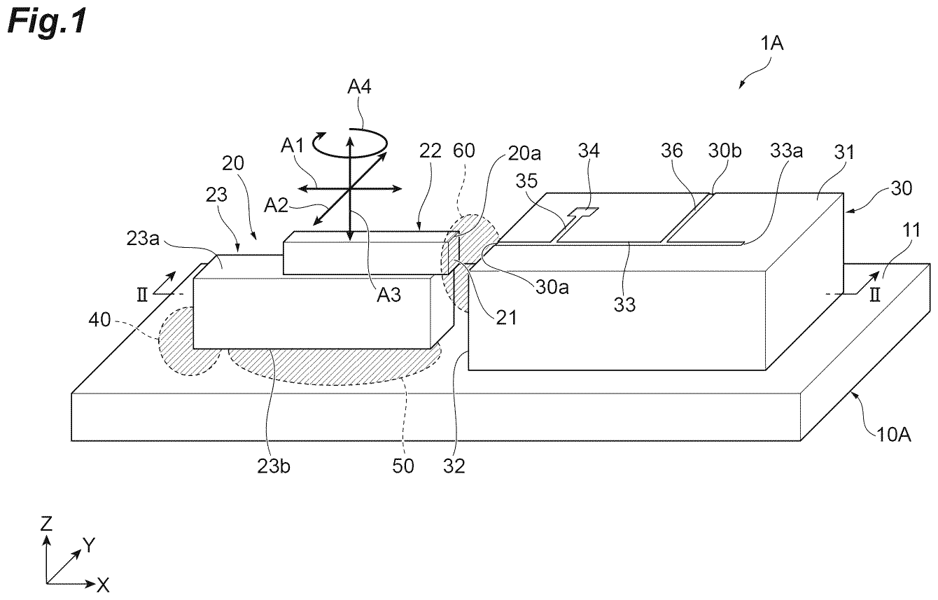

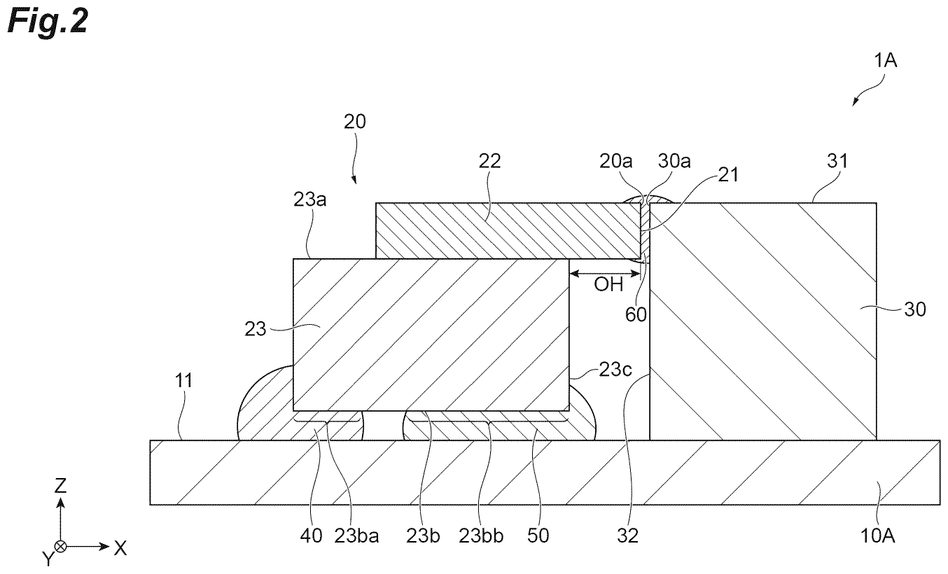

FIG. 1 is a perspective view showing an optical module 1A according to an embodiment of the present disclosure. FIG. 2 is a cross-sectional view showing the optical module 1A taken along a line II-II of FIG. 1. As shown in FIGS. 1 and 2, the optical module 1A according to this embodiment includes a base material 10A, an optical semiconductor element 20, an optical circuit element 30, a first adhesive 40, a second adhesive 50, and a third adhesive 60. FIG. 1 schematically shows the first adhesive 40, the second adhesive 50, and the third adhesive 60.

The base material 10A has a flat first surface 11. FIG. 1 shows the first surface 11 having a rectangular planar shape as an example. The planar shape of the first surface 11 is not limited thereto. The base material 10A is, for example, an insulating substrate. A metal film to be fixed to the second adhesive 50 is formed on the first surface 11.

The optical semiconductor element 20 is provided on the first surface 11. The optical semiconductor element 20 has a first optical port 20a for light incidence, light emission, or light incidence and emission in a side surface 21 thereof. The optical semiconductor device 20 shown in the example includes an optical semiconductor chip 22 and a carrier 23.

The optical semiconductor chip 22 has an end surface constituting the side face 21 and has the first optical port 20a in the end surface. The optical semiconductor chip 22 is, for example, a semiconductor optical amplifier (SOA). For example, the optical semiconductor chip 22 is made of a compound material such as indium phosphide (InP). The carrier 23 has a substantially rectangular parallelepiped appearance and has a mounting surface 23a and a bottom surface 23b opposite to the mounting surface 23a. The optical semiconductor chip 22 is mounted on the mounting surface 23a. The bottom surface 23b faces the first surface 11. The bottom surface 23b is also the bottom surface of the optical semiconductor element 20. The bottom surface 23b is a flat surface in this embodiment. The carrier 23 is obtained by forming a metal film, such as a gold (Au) film, on a surface of a ceramic material such as aluminum nitride (AlN). A back electrode of the optical semiconductor chip 22 is conductively bonded to the metal film provided on the mounting surface 23a of the carrier 23.

The optical circuit element 30 is disposed alongside the optical semiconductor element 20 on the first surface 11. For example, the optical circuit element 30 is fixed to the first surface 11 by an adhesive (not shown). The optical circuit element 30 is, for example, a silicon photonics chip (SiPh) having an optical circuit formed on a main surface 31. The optical circuit element 30 has a second optical port 30a for light incidence, light emission, or light incidence and emission in a side surface 32 thereof. The second optical port 30a faces the first optical port 20a and is optically coupled to the first optical port 20a. The third adhesive 60 is provided between the first optical port 20a and the second optical port 30a. When the third adhesive 60 is not provided, only air is present between the first optical port 20a and the second optical port 30a. An optical component, such as a lens, is not provided between the first optical port 20a and the second optical port 30a. This form is called edge coupling. A distance between the first optical port 20a and the second optical port 30a is, for example, several micrometers.

As an example, the optical circuit element 30 further includes a linear optical waveguide 33, a built-in photodiode 34, and a monitoring optical port 30b. The optical waveguide 33 is formed on the main surface 31. A first end of the optical waveguide 33 is the second optical port 30a. A second end of the optical waveguide 33 is a reflecting end 33a, and light introduced from the second optical port 30a is reflected at the reflecting end 33a and is emitted from the second optical port 30a. Therefore, the optical waveguide 33 and an optical waveguide provided in the optical semiconductor chip 22 form a laser resonator. A spot size converter may be provided between the second optical port 30a and the first end of the optical waveguide 33. Laser light generated by the optical semiconductor chip 22 and the optical waveguide 33 is emitted, for example, from an optical port (not shown) of the optical semiconductor chip 22 opposite to the first optical port 20a to the outside of the optical module 1A.

The built-in photodiode 34 is formed on the main surface 31. The built-in photodiode 34 is optically coupled to the optical waveguide 33 through an optical waveguide 35 formed on the main surface 31. The built-in photodiode 34 outputs an electrical signal corresponding to the intensity of the laser light generated in the optical waveguide 33. For example, a control device provided outside the optical module 1A controls the gain of the optical semiconductor element 20 on the basis of the electrical signal. The monitoring optical port 30b is optically coupled to the optical waveguide 33 through an optical waveguide 36 formed on the main surface 31. A portion of the laser light generated in the optical waveguide 33 is provided from the monitoring optical port 30b to the outside of the optical module 1A.

The first adhesive 40 is disposed between the optical semiconductor element 20 and the first surface 11. In the shown example, the first adhesive 40 is disposed between the bottom surface 23b of the carrier 23 and the first surface 11 and is in contact with both the bottom surface 23b and the first surface 11. In other words, the bottom surface 23b of the carrier 23 includes a first contact surface 23ba, which the first adhesive 40 contacts. The first adhesive 40 may further be in contact with the side surface of the carrier 23. The first adhesive 40 mainly includes a UV curable material cured by irradiation with ultraviolet light (UV). The UV curable material may be a UV curable resin. The first adhesive 40 fixes the optical semiconductor element 20 (the carrier 23 in the shown example) to the first surface 11. The thickness of the first adhesive 40, in other words, a gap between the bottom surface 23b of the carrier 23 and the first surface 11 is, for example, equal to or greater than 20 μm and equal to or less than 70 μm in a state in which the first adhesive 40 is cured. The first adhesive has a thermal conductance (first thermal conductance). The first thermal conductivity may be lower than 1 W/m·K after the first adhesive is cured.

The second adhesive 50 is disposed alongside the first adhesive 40 on the first surface 11 and is disposed between the optical semiconductor element 20 and the first surface 11. In the shown example, the second adhesive 50 is disposed between the bottom surface 23b of the carrier 23 and the first surface 11 and is in contact with both the bottom surface 23b and the first surface 11, more specifically, with both the metal films formed on the bottom surface 23b and the first surface 11, respectively. In other words, the bottom surface 23b of the carrier 23 includes a second contact surface 23bb, which the second adhesive 50 contacts. The second adhesive 50 may further be in contact with the side surface of the carrier 23, more specifically, the metal film formed on the side surface of the carrier 23. The second adhesive 50 mainly includes a thermosetting material cured by heating. The thermosetting material may be sintered silver or may be epoxy-containing sintered silver. The second adhesive 50 has a thermal conductivity (second thermal conductivity) higher than the thermal conductivity (first thermal conductivity) of the first adhesive 40. The second thermal conductivity may be larger than 20 W/m·K after the second adhesive is cured. The second thermal conductivity may be more than twenty times of the first thermal conductivity. The sintered silver may have a thermal conductivity higher than 100 W/m·K. The second thermal conductivity may be more than one hundred times of the first thermal conductivity. The second adhesive 50 fixes the optical semiconductor element 20 (the carrier 23 in the shown example) to the first surface 11. Moreover, the second adhesive transfers heat generated within the optical semiconductor element 20 to the base material 10A more efficiently than the first adhesive.

As shown in FIG. 2, the first adhesive 40 and the second adhesive 50 are not in contact with each other and are spaced apart from each other on the first surface 11 (or the bottom surface 23b of the carrier 23) in the cured state. In the cured state, the width of the gap between the first adhesive 40 and the second adhesive 50 is, for example, 0.05 mm or more, and, for example, 0.25 mm or less. A contact area between the second adhesive 50 and the optical semiconductor element 20 (the carrier 23 in the shown example) is larger than a contact area between the first adhesive 40 and the optical semiconductor element 20 (the carrier 23 in the shown example).

The third adhesive 60 is disposed between the first optical port 20a and the second optical port 30a and is in contact with both the first optical port 20a and the second optical port 30a. The third adhesive 60 may further be in contact with one or both of an upper surface of the optical semiconductor element 20 (an upper surface of the optical semiconductor chip 22 in the shown example) and the main surface 31 of the optical circuit element 30. The third adhesive 60 mainly includes a UV curable material having a higher UV irradiation curing speed than the UV curable material of the first adhesive 40. The UV curable material may be a UV curable resin. The third adhesive 60 is transparent to light propagating between the first optical port 20a and the second optical port 30a and performs refractive index matching between the first optical port 20a and the second optical port 30a. The third adhesive 60 is, for example, an epoxy resin, and its refractive index after curing may be between 1.4 and 1.6. Meanwhile, the optical semiconductor chip 22 protrudes in the X direction towards the optical circuit element 30 from the side surface 23c of the carrier 23 that faces the optical circuit element 30. Therefore, in the X direction, the side surface 21 of the optical semiconductor chip 22 is positioned between the side surface 23c of the carrier 23 and the optical circuit element 30. The optical semiconductor device 20 has a distance OH between the side surface 21 of the optical semiconductor chip 22 and the side surface 23c of the carrier 23 in the X direction. By providing the protrusion with the distance OH, it is possible to prevent the second adhesive 50 from coming into contact with the third adhesive 60 when the second adhesive 50 creeps up along the side surface 23c towards the optical semiconductor chip 22 in the Z direction. The distance OH may be, for example, 0.05 mm or more, and further, 0.1 mm or less.

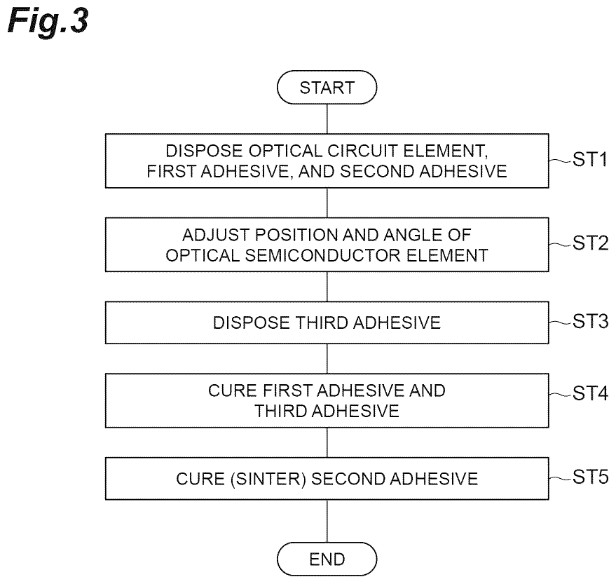

FIG. 3 is a flowchart showing a method for manufacturing the optical module 1A according to this embodiment. As shown in FIG. 3, this manufacturing method includes a first step ST1, a second step ST2, a third step ST3, a fourth step ST4, and a fifth step ST5. In the first step ST1, the optical circuit element 30, the first adhesive 40, and the second adhesive 50 are disposed on the first surface 11 of the base material 10A. At this time, the first adhesive 40 and the second adhesive 50 are applied to the first surface 11. The thickness of the first adhesive 40 and the second adhesive 50 at this time, in other words, the height from the first surface 11 to the vertex of each of the first adhesive 40 and the second adhesive 50 is, for example, equal to or greater than 70 μm and is, for example, 100 μm. This height indicates the height before optical axis adjustment which will be described below is performed.

In the second step ST2, the optical semiconductor element 20 is held by a chuck or the like. Then, light is emitted from the first optical port 20a of the optical semiconductor element 20 by supplying a driving current to the optical semiconductor element 20 through the chuck or the like. The position and angle of the optical semiconductor element 20 are adjusted such that the first optical port 20a is optically coupled to the second optical port 30a while the optical semiconductor element 20 (specifically, the bottom surface 23b of the carrier 23) is brought into contact with the first adhesive 40 and the second adhesive 50 (optical axis adjustment). The optically coupled state between the first optical port 20a and the second optical port 30a can be known, for example, by detecting the magnitude of an electric signal output from the built-in photodiode 34 or the intensity of the light emitted from the monitoring optical port 30b. The adjustment of the position and angle of the optical semiconductor element 20 includes adjustment of the position in an optical axis direction (an arrow A1 shown in FIG. 1), adjustment of the position in a lateral direction intersecting the optical axis direction (an arrow A2 shown in FIG. 1), adjustment of the position in a normal direction to the first surface 11 (an arrow A3 shown in FIG. 1), and adjustment of the angle around an axis along a normal line to the first surface 11 (an arrow A4 shown in FIG. 1). The optical axis adjustment is performed such that the magnitude of the electric signal output from the built-in photodiode 34 or the intensity of the light emitted from the monitoring optical port 30b is greater than a predetermined value. The thickness of the first adhesive 40 and the second adhesive 50 can be changed by adjusting the position in the normal direction to the first surface 11 during the optical axis adjustment. Before curing, each of the first adhesive 40 and the second adhesive 50 is likely to be deformed by an external force. Further, in the following description, for convenience, in some cases, the optical axis direction is referred to as an X direction, the lateral direction intersecting the optical axis direction is referred to as a Y direction, and a height direction intersecting the X direction and the Y direction is referred to as a Z direction.

In the third step ST3, the third adhesive 60 is disposed (applied) between the first optical port 20a and the second optical port 30a while the optical semiconductor element 20 subjected to the optical axis adjustment is held at the position adjusted for the optical coupling by the chuck or the like and the position and angle of the optical semiconductor element 20 are maintained. In the fourth step ST4, the first adhesive 40 and the third adhesive 60 are cured by irradiation with ultraviolet light while the optical semiconductor element 20 subjected to the optical axis adjustment is held by the chuck or the like and the position and angle of the optical semiconductor element 20 are maintained. As described above, since the third adhesive 60 mainly includes the UV curing material having a higher curing speed than the UV curing material of the first adhesive 40, the third adhesive 60 is cured faster than the first adhesive 40 at this time. When the third adhesive 60 is cured, the periphery of the exposed first adhesive 40 may be temporarily covered with a shielding material such that the first adhesive 40 is not exposed to ultraviolet light.

In the fifth step ST5, in a state in which the first adhesive 40 and the third adhesive 60 are already cured, the second adhesive 50 is cured (sintered) by heating. In the fifth step ST5, a plurality of works in progress that have been subjected to the fourth step ST4 may be put into a heating furnace, and the second adhesives 50 of the plurality of works in progress may be collectively cured. The optical module 1A according to this embodiment is manufactured by the above-described steps.

The effects obtained by the optical module 1A and the method for manufacturing the optical module 1A according to this embodiment described above will be described. In the optical module 1A according to this embodiment, the optical semiconductor element 20 is fixed to the first surface 11 of the base material 10A by the first adhesive 40 and the second adhesive 50. The first adhesive 40 mainly includes the UV curable material. The second adhesive 50 has a thermal conductivity (second thermal conductivity) than a thermal conductivity (first thermal conductivity) of the first adhesive 40 and mainly includes the thermosetting material. When the optical module 1A is manufactured, the optical axis adjustment is performed in a state in which the first adhesive 40 and the second adhesive 50 can be deformed, and the first adhesive 40 can be cured by performing irradiation with ultraviolet light while maintaining the position of the optical semiconductor element 20 subjected to the optical axis adjustment using the chuck or the like. Then, the second adhesive 50 can be cured by heating in a state in which the position of the optical semiconductor element 20 subjected to the optical axis adjustment is maintained by the first adhesive 40. Therefore, according to the optical module 1A of this embodiment, it is possible to fix the optical semiconductor element 20 to the base material 10A using the thermosetting material with high heat dissipation performance while maintaining the position of the optical semiconductor element 20 subjected to the optical axis adjustment. As a result, it is possible to improve the heat dissipation performance from the optical semiconductor element 20 to the base material 10A while preventing the deviation between the optical axes of the first optical port 20a and the second optical port 30a when the second adhesive 50 is thermally cured. In addition, thermal resistance from the bottom surface 23b of the carrier 23 to the first surface 11 is, for example, equal to or less than 5 K/W.

As in this embodiment, the optical semiconductor element 20 may include the optical semiconductor chip 22 having the first optical port 20a and the carrier 23 that has the optical semiconductor chip 22 mounted thereon and is fixed to the first surface 11 by the first adhesive 40 and the second adhesive 50. In that case, even when the thickness of the optical semiconductor chip 22 is smaller than the thickness of the optical circuit element 30, the height of the first optical port 20a can be matched with the height of the second optical port 30a.

As described above, the UV curable material may be a UV curable resin. In this case, it is possible to easily fix the optical semiconductor element 20 to the base material 10A after the optical axis adjustment. Therefore, the optical semiconductor element 20 can be fixed to the base material 10A with sufficient strength by the first adhesive 40. As a result, it is possible to prevent the deviation between the optical axes of the first optical port 20a and the second optical port 30a when the second adhesive 50 is thermally cured.

As described above, the thermosetting material may be sintered silver. The sintered silver has an extremely high thermal conductivity. Therefore, in this case, it is possible to reduce the thermal resistance between the optical semiconductor element 20 and the base material 10A. This makes it possible to more efficiently transfer heat from optical semiconductor element 20 to the base material 10A.

As described above, the thermosetting material may be epoxy-containing sintered silver. When the second adhesive 50 includes the epoxy-containing sintered silver, the adhesion between the second adhesive 50 and the optical semiconductor element 20 is increased. As a result, it is possible to suppress shrinkage of the second adhesive 50 during sintering, and the second adhesive 50 can be less likely to peel from the optical semiconductor element 20.

As in this embodiment, the first adhesive 40 and the second adhesive 50 may be spaced apart from each other on the first surface 11 (or the bottom surface 23b of the carrier 23). In this case, the mixing of the first adhesive 40 and the second adhesive 50 before curing is avoided. Therefore, it is possible to prevent the curing of the first adhesive 40 from being hindered by the second adhesive 50.

As in this embodiment, the optical module 1A may further include the third adhesive 60 disposed between the first optical port 20a and the second optical port 30a. The third adhesive 60 may mainly include a UV curable material having a faster curing speed (that is, higher reactivity) than the UV curable material of the first adhesive 40. In this case, when irradiation with ultraviolet light is performed, the third adhesive 60 is cured faster than the first adhesive 40. Therefore, it is possible to more firmly maintain the optically coupled state between the first optical port 20a and the second optical port 30a after the optical axis adjustment. In addition, when it is possible to selectively irradiate only the third adhesive 60 with ultraviolet light without irradiating the first adhesive 40 with ultraviolet light, the curing speed of the UV curable material of the third adhesive 60 may be the same as the curing speed of the UV curable material of the first adhesive 40.

As in this embodiment, the contact area between the second adhesive 50 and the optical semiconductor element 20 may be larger than the contact area between the first adhesive 40 and the optical semiconductor element 20. Heat from the optical semiconductor element 20 can be more efficiently transferred to the base material 10A by making the contact area of the second adhesive 50 larger than the contact area of the first adhesive 40 while setting the contact area of the first adhesive 40 to a value at which fixing strength can be sufficiently ensured. The fixing strength of the first adhesive 40 is, for example, equal to or greater than a value at which it is possible to suppress the deviation between the optical axes of the first optical port 20a and the second optical port 30a when the second adhesive 50 is thermally cured.

In the manufacturing method according to this embodiment, the optical semiconductor element 20 is fixed to the first surface 11 of the base material 10A by the first adhesive 40 and the second adhesive 50. The first adhesive 40 mainly includes a UV curable material. The second adhesive 50 has a thermal conductivity (second thermal conductivity) higher than a thermal conductivity (first thermal conductivity) of the first adhesive 40 and mainly includes a thermosetting material. In the step of curing the first adhesive 40, irradiation with ultraviolet light can be performed while the position of the optical semiconductor element 20 subjected to the optical axis adjustment is maintained by the chuck or the like to cure the first adhesive 40 in a state in which the second adhesive 50 is uncured. Then, in the step of curing the second adhesive 50, the second adhesive 50 can be cured by heating in a state in which the position of the optical semiconductor element 20 subjected to the optical axis adjustment is maintained by the cured first adhesive 40. Therefore, according to the manufacturing method of this embodiment, it is possible to fix optical semiconductor element 20 to the base material 10A using the thermosetting material with high heat dissipation performance while maintaining the position of the optical semiconductor element 20 subjected to the optical axis adjustment. As a result, it is possible to efficiently transfer the heat from the optical semiconductor element 20 to the base material 10A while preventing the deviation between the optical axes of the first optical port 20a and the second optical port 30a.

### First Modification

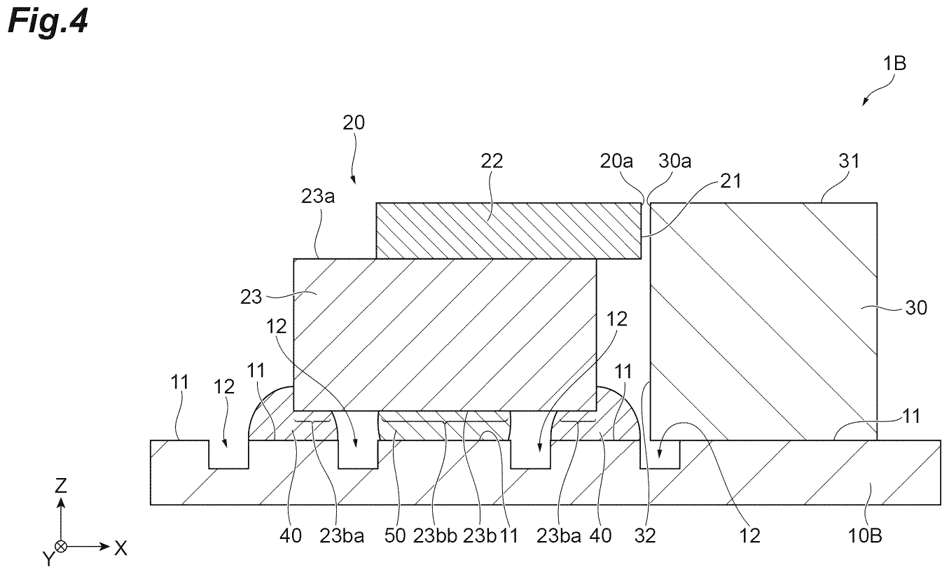

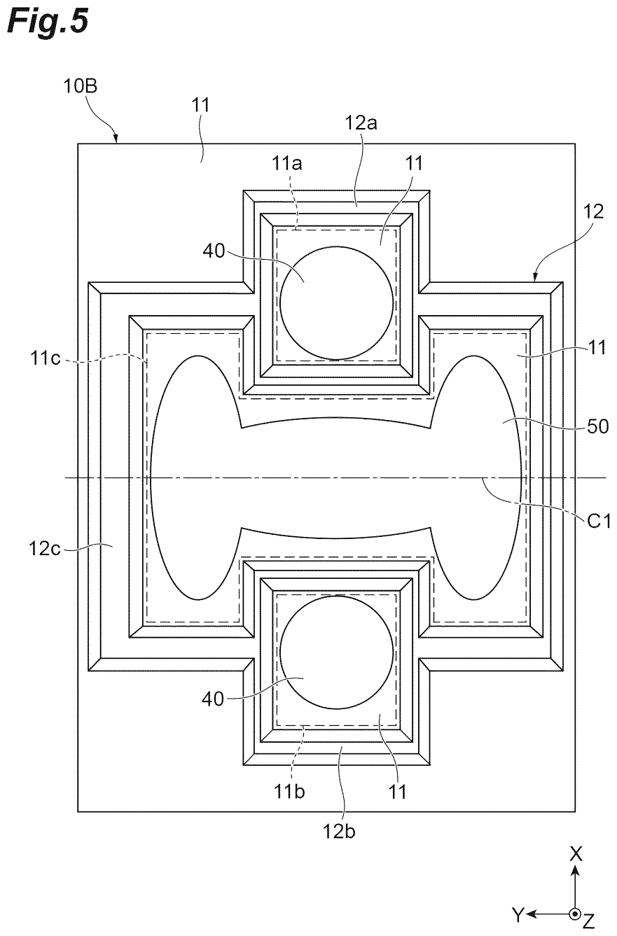

FIG. 4 is a cross-sectional view showing an optical module 1B according to a first modification of the above-described embodiment. The optical module 1B according to this modification differs from the optical module 1A according to the above-described embodiment in the following points and is the same as the optical module 1A according to the above-described embodiment in points other than the following points. In the optical module 1B according to this modification, the provision of the third adhesive 60 is omitted. In addition, the optical module 1B according to this modification includes a base material 10B instead of the base material 10A. FIG. 5 is a plan view showing the base material 10B, the first adhesive 40, and the second adhesive 50. Further, in the optical module 1B according to this modification, the provision of the third adhesive 60 is omitted, but the third adhesive 60 may be provided as in the optical module 1A. For example, the third adhesive 60 may be provided for refractive index matching between the first optical port 20a and the second optical port 30a. The third adhesive 60 has a refractive index closer to the refractive index of the optical semiconductor chip 22 and the optical circuit element 30 than to the refractive index of air (refractive index matching). This suppresses reflection between the first optical port 20a and the second optical port 30a. In the optical modules 1A and 1B, the optical semiconductor element 20 is mainly fixed to the base material 10A or 10B by the first adhesive 40 and the second adhesive 50.

As shown in FIGS. 4 and 5, in this modification, the first adhesive 40 is provided on two regions, between which the second adhesive 50 is interposed, on the first surface 11. In other words, one region in which the first adhesive 40 is provided, a region in which the second adhesive 50 is provided, and another region in which the first adhesive 40 is provided are arranged side by side in this order. The arrangement direction may coincide with the arrangement direction (X direction) of the optical semiconductor elements 20 and the optical circuit elements 30. Additionally, on the bottom surface 23b of the carrier 23, the first contact surface 23ba, which the first adhesive 40 contacts, the second contact surface 23bb, which the second adhesive 50 contacts, and another first contact surface 23ba, which the first adhesive 40 contacts, are arranged in this order.

The base material 10B has the first surface 11 and a groove 12 (recessed portion) formed in the first surface 11. The groove 12 is formed at least between the first adhesive 40 and the second adhesive 50 when viewed from a normal direction (Z direction) to the first surface 11. As shown in FIG. 4, in a cross section extending in the X direction and the Z direction, the groove 12 can have various shapes such as a rectangular shape, an inverted trapezoidal shape, and a semicircular shape. For example, the width (the length in the X direction in FIG. 4) of the groove 12 is 0.1 mm, and the depth (the length in the Z direction) of the groove 12 is 0.12 mm. The groove 12 may be further formed on the opposite side of the second adhesive 50 when viewed from the first adhesive 40 and on the opposite side of the first adhesive 40 when viewed from the second adhesive 50. In the example shown in FIG. 5, the groove 12 includes a portion 12a, a portion 12b, and a portion 12c. The portion 12a surrounds one region 11a in which the first adhesive 40 is provided. The portion 12b surrounds another region 11b in which the first adhesive 40 is provided. The portion 12c surrounds a region 11c in which the second adhesive 50 is provided. The shape of the portion 12a and the portion 12b when viewed from the normal direction (Z direction) to the first surface 11 is, for example, a square shape or a rectangular shape. The shape of the portion 12c when viewed from the normal direction (Z direction) to the first surface 11 may be a square shape or a rectangular shape. Alternatively, the shape of the portion 12c when viewed from the normal direction (Z direction) to the first surface 11 may be a shape obtained by cutting out the portion 12a and the portion 12b from a shape square or a rectangular shape as shown in FIG. 5. In this case, the region in which the second adhesive 50 is provided has a shape such as an H-shape. In FIG. 5, the portion 12a and the portion 12b are arranged in the X direction with the region 11c interposed therebetween. The portion 12a and the portion 12b may be arranged in the Y direction with the region 11c interposed therebetween.

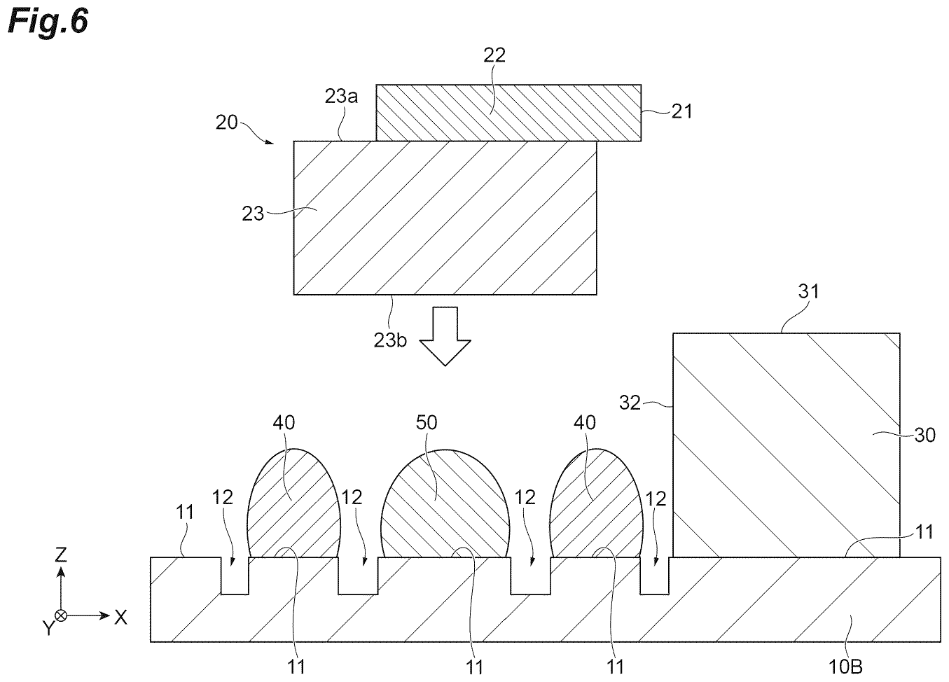

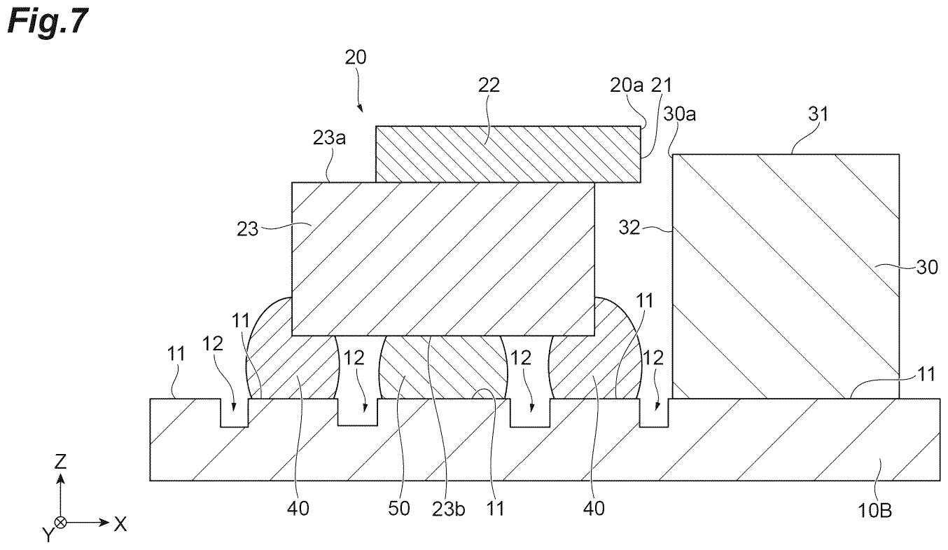

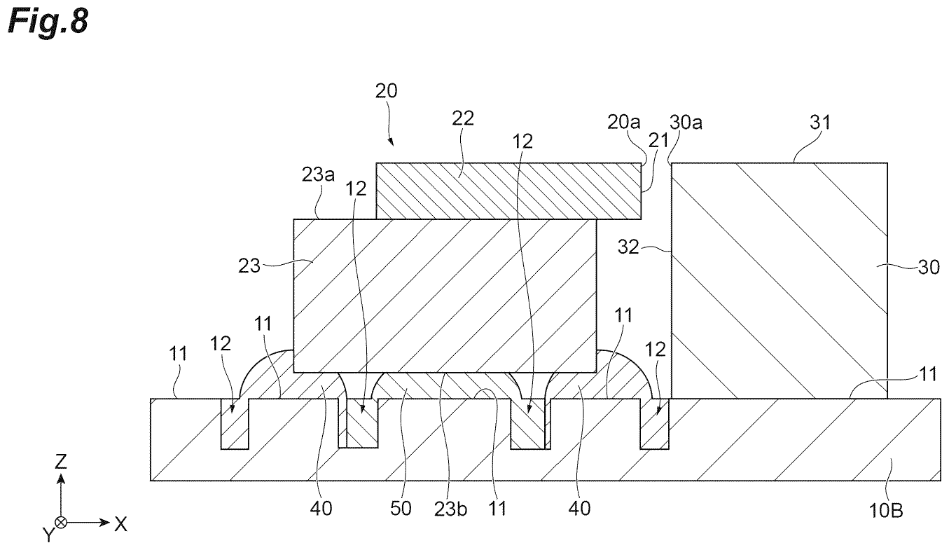

FIGS. 6, 7 and 8 are cross-sectional views showing a second step ST2 (see FIG. 3) in a process of manufacturing the optical module 1B. First, the optical semiconductor element 20 held by the chuck or the like is brought close to the first adhesive 40 and the second adhesive 50 disposed on the first surface 11 (see FIG. 6). At this time, the first adhesive 40 and the second adhesive 50 are applied thickly in advance, considering a variation in the height from the bottom surface 23b of the optical semiconductor element 20 to the first optical port 20a due to manufacturing errors. Then, the optical semiconductor element 20 (specifically, the bottom surface 23b of the carrier 23) is brought into contact with the first adhesive 40 and the second adhesive 50 (see FIG. 7). Then, the position and angle of the optical semiconductor element 20 are adjusted such that the first optical port 20a is optically coupled to the second optical port 30a (see FIG. 8). At this time, since the height position of the first optical port 20a is determined by the height position of the second optical port 30a, the variation in the height from the bottom surface 23b of the optical semiconductor element 20 to the first optical port 20a is absorbed by the deformation of the first adhesive 40 and the second adhesive 50 (a change in the thickness in the Z direction). When the height from the bottom surface 23b to the first optical port 20a is large, the first adhesive 40 and the second adhesive 50 are pressed by the optical semiconductor element 20, and the thickness of the first adhesive 40 and the second adhesive 50 is reduced. In this case, excess portions of the first adhesive 40 and the second adhesive 50 spread in the X direction and approach each other. In addition, the excess portions of the first adhesive 40 and the second adhesive 50 also spread in the Y direction.

In this modification, since the base material 10B has the groove 12 formed between the first adhesive 40 and the second adhesive 50, the excess portions of the first adhesive 40 and second adhesive 50 that have spread in the direction in which the excess portions approach each other can be dropped into the groove 12. Therefore, the mixing of the first adhesive 40 and the second adhesive 50 on the first surface 11 before curing is avoided. As a result, it is possible to prevent the curing of the first adhesive 40 on the first surface 11 from being hindered by the second adhesive 50. For example, when uncured sintered silver is mixed with an uncured UV curable resin, there is a concern that the UV curable resin will not be cured sufficiently. In this case, the first adhesive 40 and the second adhesive 50 mix within the groove 12. However, even if the curing of the first adhesive 40 within the groove 12 is insufficient, the impact on the fixation strength between the substrate 10B and the carrier 23, as well as the impact on the heat dissipation through the second adhesive 50, is minimal.

In this modification, the first adhesive 40 is provided on a plurality of regions 11a and 11b, between which the second adhesive 50 is interposed, on the first surface 11. In this case, when the second adhesive 50 is cured by heating, it is possible to suppress the inclination of the optical semiconductor element 20 with respect to the first surface 11 and to more stably maintain the position of the first optical port 20a after the optical axis adjustment. As a result, it is possible to more reliably prevent the deviation between the optical axes of the first optical port 20a and the second optical port 30a.

As shown in FIG. 5, the regions 11a and 11b may be disposed so as to be line-symmetric with respect to an axis line C1 along the first surface 11. In this case, it is possible to suppress the inclination of the optical semiconductor element 20 after the first adhesive 40 is cured and to more stably maintain the position of the first optical port 20a after the optical axis adjustment. The axis line C1 may be a center line of the region 11c in the X direction.

As in this modification, the region 11a in which the first adhesive 40 is provided may be surrounded by the portion 12a of the groove 12, and the region 11b in which the first adhesive 40 is provided may be surrounded by the portion 12b of the groove 12. In this case, since surface tension caused by an edge portion of the groove 12 occurs in the first adhesive 40, it is possible to increase the thickness of the first adhesive 40 having low thixotropy before the optical semiconductor element 20 is brought into contact with the first adhesive 40. As a result, it is possible to increase the absorption width of the variation in the height from the bottom surface 23b of the optical semiconductor element 20 to the first optical port 20a due to manufacturing errors, that is, the range in which the thickness of the first adhesive 40 can be changed.

### Second Modification

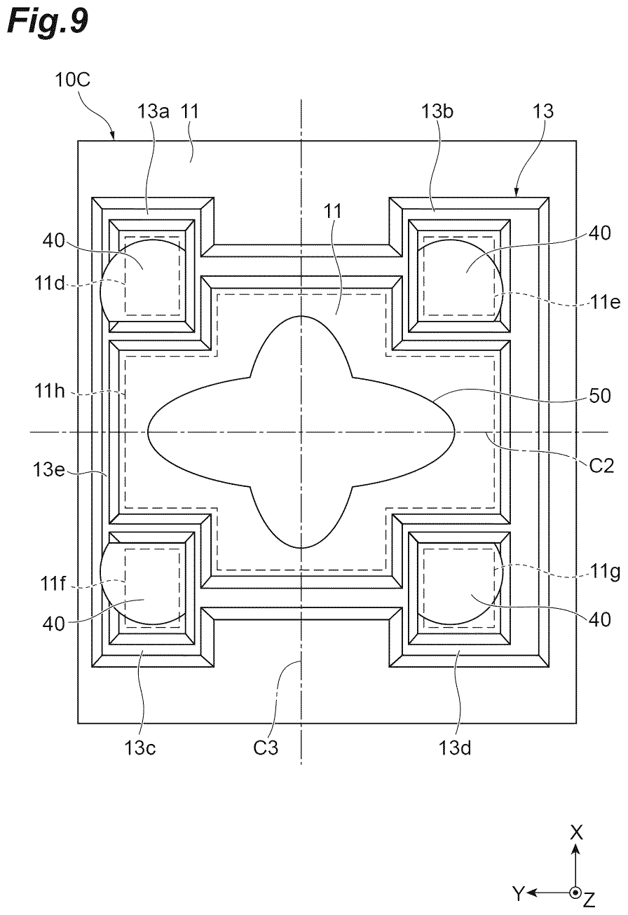

FIG. 9 is a plan view showing a base material 10C, a first adhesive 40, and a second adhesive 50 according to a second modification. In this modification, four regions 11d, 11e, 11f, and 11g in which the first adhesive 40 is provided are disposed at four corners of a region 11h in which the second adhesive 50 is provided, respectively. The base material 10C has a groove (recessed portion) 13. The groove 13 includes a portion 13a, a portion 13b, a portion 13c, a portion 13d, and a portion 13e. The portions 13a to 13d surround the four regions 11d to 11g in which the first adhesive 40 is provided, respectively. The portion 13e surrounds the region 11h in which the second adhesive 50 is provided. The shape of the portions 13a to 13d when viewed from the normal direction (Z direction) to the first surface 11 is, for example, a square shape or a rectangular shape. The shape of the portion 13e when viewed from the normal direction (Z direction) to the first surface 11 may be a square shape or a rectangular shape. Alternatively, the shape of the portion 13e when viewed from the normal direction (Z direction) to the first surface 11 may be a shape obtained by cutting out parts of the portions 13a to 13d from a shape square or a rectangular shape as shown in FIG. 9. In this case, the region 11h in which the second adhesive 50 is provided has a shape such as a cross shape.

Even in the example shown in FIG. 9, since the base material 10C has the groove 13 formed between the first adhesive 40 and the second adhesive 50, the first adhesive 40 and the second adhesive 50 that have spread in the direction in which the adhesives approach each other during the optical axis adjustment can be dropped into the groove 13. Therefore, the mixing of the uncured first adhesive 40 and the uncured second adhesive 50 on the first surface 11 is avoided. As a result, it is possible to prevent the curing of the first adhesive 40 on the first surface 11 from being hindered by the mixing of the second adhesive 50.

Even in the example shown in FIG. 9, the first adhesive 40 is provided on the plurality of regions 11d, 11e, 11f, and 11g, between which the second adhesive 50 is interposed, on the first surface 11. In this case, when the second adhesive 50 is cured by heating, the optical semiconductor element 20 is fixed to the first surface 11 by the first adhesive 40 cured in advance. Therefore, it is possible to suppress the inclination of the optical semiconductor element 20 and to more stably maintain the position of the first optical port 20a after the optical axis adjustment. As a result, it is possible to more reliably prevent the deviation between the optical axes of the first optical port 20a and the second optical port 30a.

Even in the example shown in FIG. 9, the regions 11d to 11g are disposed so as to be line-symmetric with respect to axis lines C2 and C3 along the first surface 11. In this case, it is possible to suppress the inclination of the optical semiconductor element 20 after the first adhesive 40 is cured and to more stably maintain the position of the first optical port 20a after the optical axis adjustment. The axis line C2 may be a center line of the region 11h in the X direction, and the axis line C3 may be a center line of the region 11h in the Y direction.

Even in the example shown in FIG. 9, the regions 11d to 11g in which the first adhesive 40 is provided may be surrounded by the portions 13a to 13d of the groove 13, respectively. In this case, since surface tension caused by an edge portion of the groove 13 is occurs in the first adhesive 40, it is possible to increase the thickness of the first adhesive 40 having low thixotropy before the optical semiconductor element 20 is brought into contact with the first adhesive 40. As a result, it is possible to increase the absorption range of the variation in the height from the bottom surface 23b of the optical semiconductor element 20 to the first optical port 20a due to manufacturing errors, that is, the range in which the thickness of the first adhesive 40 can be changed.

### Third Modification

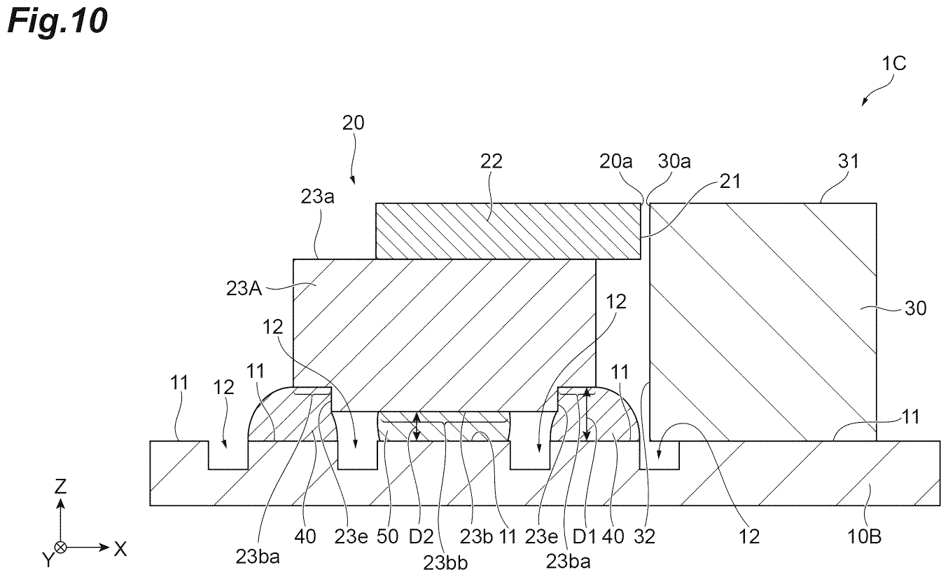

FIG. 10 is a cross-sectional view of the optical module 1C according to a third modification. The optical module 1C of this modification differs from the optical module 1B of the first modification in the following points and is the same as the optical module 1B of the first modification in points other than the following points. The optical module 1C of this modification includes a carrier 23A instead of the carrier 23. Similar to the carrier 23 of the above embodiment, the carrier 23A has a substantially rectangular parallelepiped appearance and includes a mounting surface 23a and a bottom surface 23b. The optical semiconductor chip 22 is mounted on the mounting surface 23a. The bottom surface 23b faces the first surface 11. The material of the carrier 23A is the same as that of the carrier 23 of the above embodiment.

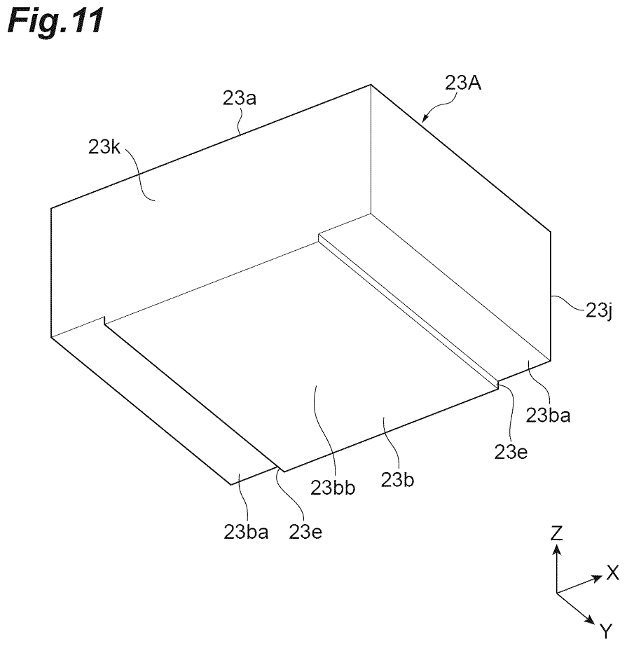

FIG. 11 is a perspective view showing the appearance of the carrier 23A. As shown in FIGS. 10 and 11, in the carrier 23A, both the first contact surface 23ba and the second contact surface 23bb are flat surfaces, and the distance D2 between the second contact surface 23bb and the first surface 11 is smaller than the distance D1 between the first contact surface 23ba and the first surface 11. In other words, the first contact surface 23ba is recessed in the direction toward the mounting surface 23a relative to the second contact surface 23bb. That is, the first contact surface 23ba is positioned closer to the mounting surface 23a relative to a virtual plane including the second contact surface 23bb. Therefore, a step 23e is formed between the first contact surface 23ba and the second contact surface 23bb. The surface of the step 23e is either perpendicular to or inclined to the bottom surface 23b. The difference between the distance D2 and the distance D1 (D2−D1), that is, the height of the step 23e, is, for example, 20 μm or more and 50 μm or less. The distance D1 is, for example, 20 μm or more and 70 μm or less.

One of the two first contact surfaces 23ba of the carrier 23A extends along the Y direction while contacting the first adhesive 40 provided on the region 11a (see FIG. 5). The other of the two first contact surfaces 23ba extends along the Y direction while contacting the first adhesive 40 provided on the region 11b (see FIG. 5). Both ends of these first contact surfaces 23ba reach the pair of side surfaces of the carrier 23A, namely, the side surfaces 23j and 23k, which intersect the Y direction and face each other.

The position of the step 23e in the X direction may be determined based on the relative positional relationship with the groove 12. That is, as viewed from the normal direction of the bottom surface 23b, the step 23e may be positioned over the groove 12 or positioned outward relative to the groove 12.

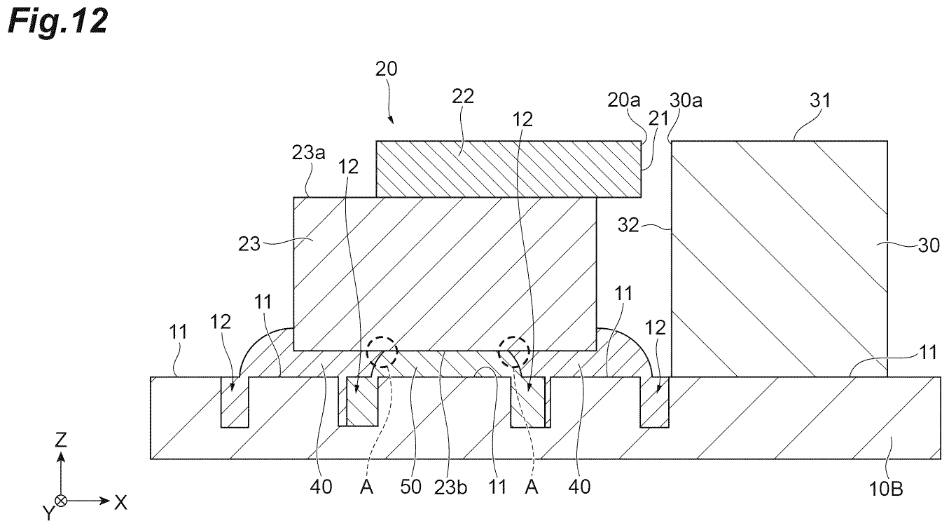

The effects obtained by this modification will be described. FIG. 12 is a diagram for explaining the issues associated with the optical module according to the above-described embodiment and each modification. As described above, on the first surface 11, the first adhesive 40 and the second adhesive 50 are spaced apart from each other. In the first and second modifications, the excess portions of the first adhesive 40 and the second adhesive 50, which spread in the direction approaching each other before curing, are dropped into the groove 12. However, the first adhesive 40, which has relatively high fluidity before curing, may spread along the bottom surface 23b of the carrier 23, and in such a case, the first adhesive 40 may contact the second adhesive 50 on and near the bottom surface 23b as shown in part A of FIG. 12. As a result, the first adhesive 40 and the second adhesive 50 may mix on the first surface 11, and the curing of the first adhesive 40 on the first surface 11 may be hindered by the second adhesive 50. Additionally, if the first adhesive 40 enters between the second adhesive 50 and the bottom surface 23b, the area of the second contact surface 23bb decreases, and heat dissipation is reduced.

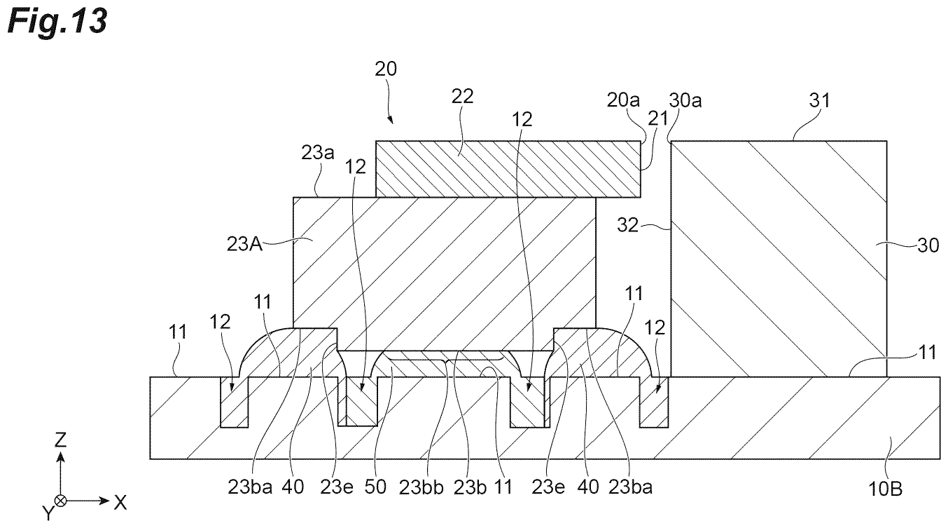

In response to the above issues, in this modification, the distance D2 between the second contact surface 23bb and the first surface 11 is smaller than the distance D1 between the first contact surface 23ba and the first surface 11, on the bottom surface 23b of the carrier 23A. In this case, as shown in FIG. 13, even if the first adhesive 40 spreads along the bottom surface 23b before curing, the spread portion of the first adhesive 40 is dammed by the step 23e, so that the first adhesive 40 is prevented from spreading to the second contact surface 23bb. Therefore, according to this modification, it is possible to avoid the mixing of the first adhesive 40 and the second adhesive 50 on or near the bottom surface 23b, and to prevent the curing of the first adhesive 40 on or near the bottom surface 23b from being hindered by the second adhesive 50. Furthermore, it is possible to prevent the first adhesive 40 from entering between the second adhesive 50 and the bottom surface 23b to increase the area of the second contact surface 23bb, so that heat dissipation is improved.

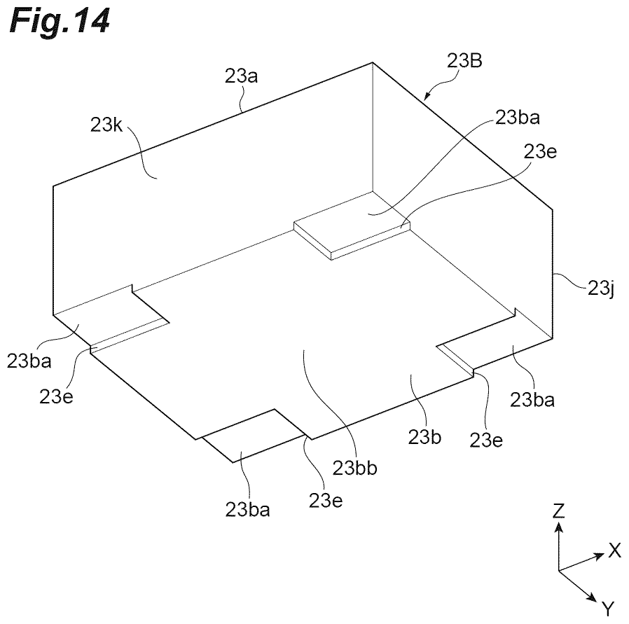

FIG. 14 is a perspective view showing the appearance of the carrier 23B as another form of this modification. The carrier 23B differs from the carrier 23A in that the carrier 23B has the first contact surface 23ba at each of the four corners of the bottom surface 23b. By using this carrier 23B in the second modification shown in FIG. 9, the effects of this modification described above can be obtained.

### Fourth Modification

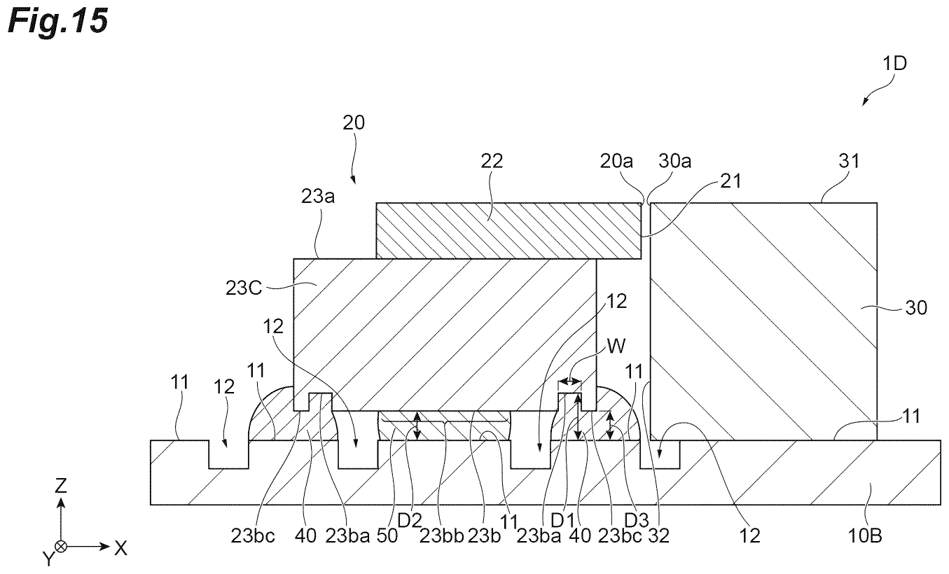

FIG. 15 is a cross-sectional view of the optical module 1D according to a fourth modification. The optical module 1D of this modification differs from the optical module 1C of the third modification in the following points and is the same as the optical module 1C of the third modification in points other than the following points. The optical module 1D of this modification includes a carrier 23C instead of the carrier 23A. Similar to the carrier 23 of the above embodiment, the carrier 23C has a substantially rectangular parallelepiped appearance and includes a mounting surface 23a and a bottom surface 23b. The optical semiconductor chip 22 is mounted on the mounting surface 23a. The bottom surface 23b faces the first surface 11. The material of the carrier 23C is the same as that of the carrier 23 of the above embodiment.

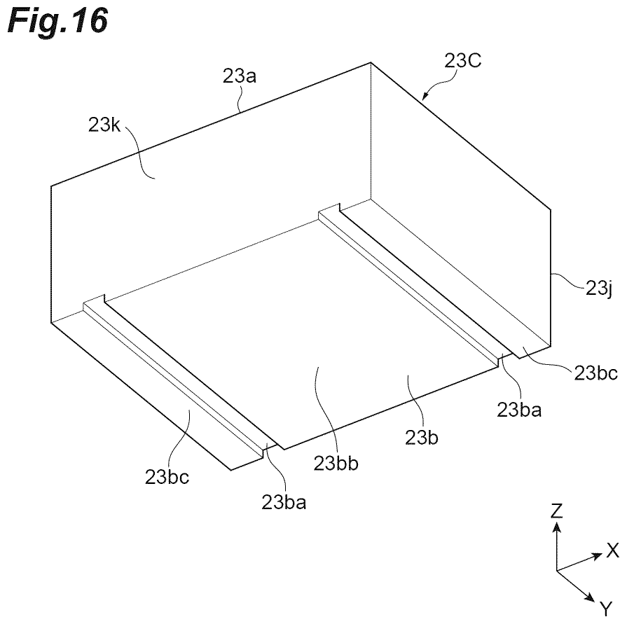

FIG. 16 is a perspective view showing the appearance of the carrier 23C. As shown in FIGS. 15 and 16, the bottom surface 23b of the carrier 23C includes a third contact surface 23bc that the first adhesive 40 contacts in addition to the first contact surface 23ba and the second contact surface 23bb. As viewed from the normal direction of the bottom surface 23b, the first contact surface 23ba is positioned between the second contact surface 23bb and the third contact surface 23bc. In other words, the third contact surface 23bc is positioned outward relative to the first contact surface 23ba and on the opposite side of the first contact surface 23ba relative to the second contact surface 23bb. The third contact surface 23bc is a flat surface similarly to the first contact surface 23ba and the second contact surface 23bb. The distance D3 between the third contact surface 23bc and the first surface 11 is smaller than the distance DI between the first contact surface 23ba and the first surface 11. In other words, the third contact surface 23bc protrudes toward the first surface 11 from the first contact surface 23ba. That is, the third contact surface 23bc is positioned closer to the first surface 11 relative to a virtual plane including the first contact surface 23ba. Therefore, the first contact surface 23ba forms the bottom surface of a groove sandwiched between the second contact surface 23bb and the third contact surface 23bc. The side surfaces of the groove are either perpendicular to or inclined to the bottom surface 23b. The shape of the groove in a cross-section perpendicular to the extending direction of the first contact surface 23ba is, for example, rectangular. The cross-sectional shape of the groove is not limited to this and various shapes such as trapezoidal or semicircular can be applied. The width W of the groove in the direction orthogonal to the extending direction is, for example, 50 μm or more and 140 μm or less. The depth of the groove, that is, the difference between the distance D2 and the distance D1 (D2−D1), is, for example, 50 μm or more and 100 μm or less.

The first adhesive 40 enters the groove and contacts the inner surface of the groove. As shown in FIG. 16, the groove and the first contact surface 23ba extend linearly along the Y direction. This allows the groove to be easily formed using, for example, a dicing blade. Both ends of the groove and the first contact surface 23ba reach the side surfaces 23j and 23k of the carrier 23A. The distance D3 may be greater than, smaller than, or equal to the distance D2 between the second contact surface 23bb and the first surface 11.

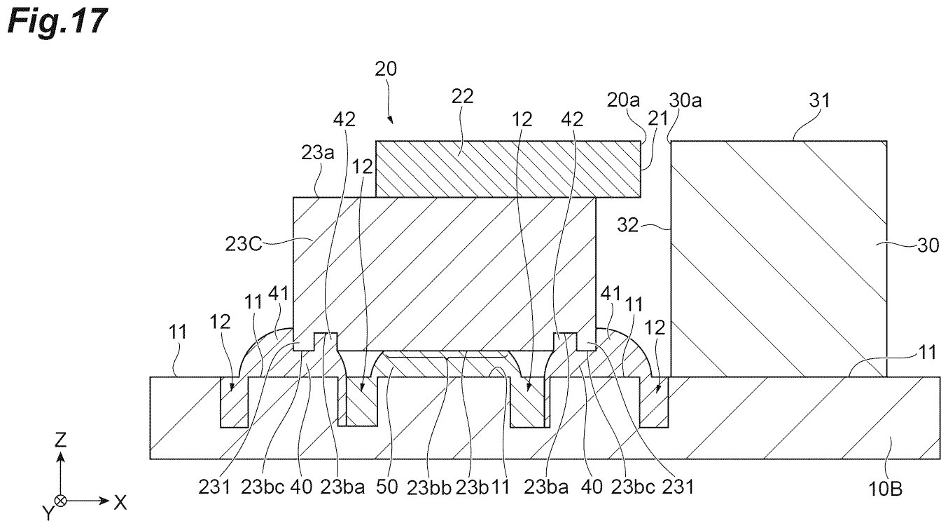

In this modification as well, the distance D2 between the second contact surface 23bb and the first surface 11 is smaller than the distance D1 between the first contact surface 23ba and the first surface 11. Therefore, as shown in FIG. 17, the first adhesive 40 is prevented from spreading to the second contact surface 23bb. Thus, it is possible to avoid the mixing of the first adhesive 40 and the second adhesive 50 on or near the bottom surface 23b to prevent the curing of the first adhesive 40 on or near the bottom surface 23b from being hindered by the second adhesive 50.

Additionally, as shown in FIG. 17, in case the cured first adhesive 40 reaches the side surface of the carrier 23C, the portion 41 of the first adhesive 40 located on the side surface of the carrier 23C and the portion 42 of the first adhesive 40 located on the first contact surface 23ba (i.e., inside the groove) sandwich a part of the carrier 23C, that is, the part 231 of the carrier 23C including the third contact surface 23bc, from both sides. This enhances the fixation strength between the carrier 23C and the substrate 10B.

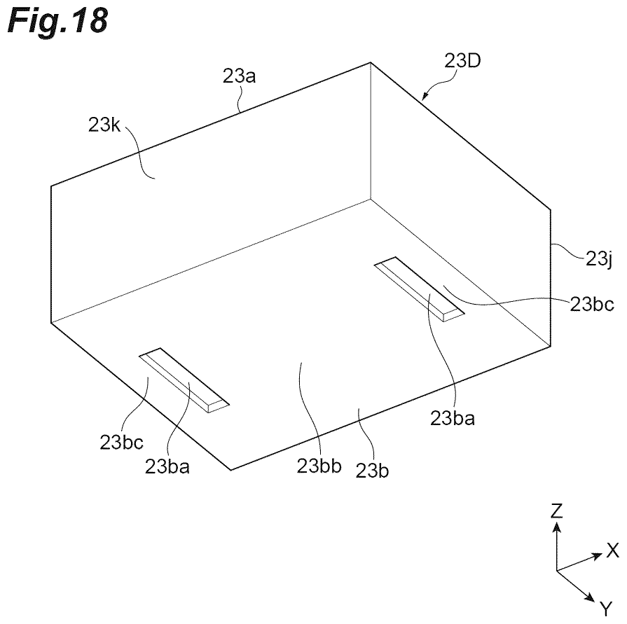

FIG. 18 is a perspective view showing the appearance of the carrier 23D as another form of this modification. The carrier 23D differs from the carrier 23C in that the ends of the groove with the first contact surface 23ba as the bottom do not reach both the side surfaces 23j and 23k. In other words, there is a gap between the first contact surface 23ba and each of the side surfaces 23j and 23k. Even in this form, the effects of this modification described above can be obtained. However, in the form shown in FIG. 18, since the groove cannot be formed using a dicing blade, the groove is formed by sandblasting or other methods.

### Fifth Modification

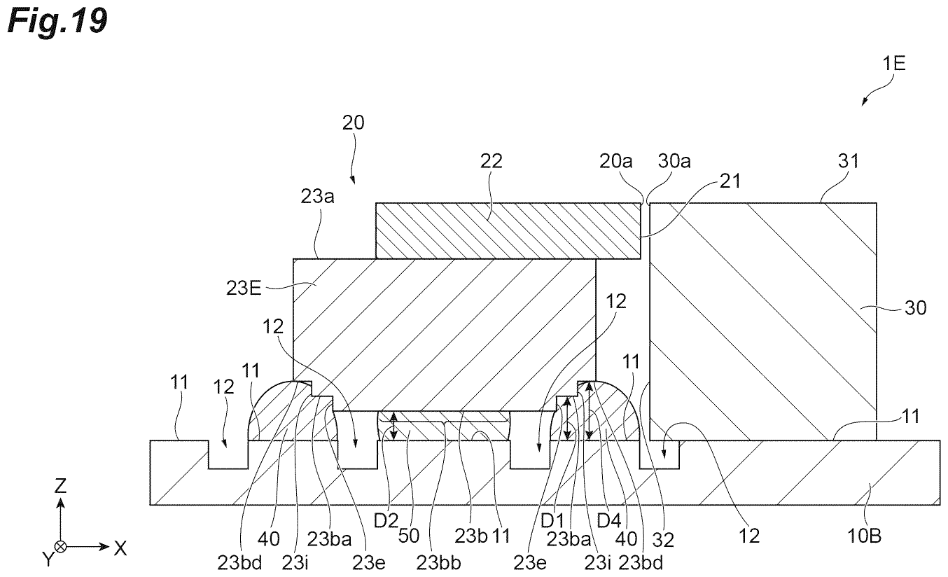

FIG. 19 is a cross-sectional view of the optical module 1E according to a fifth modification. The optical module 1E of this modification differs from the optical module 1C of the third modification in the following points and is the same as the optical module 1C of the third modification in points other than the following points. The optical module 1E of this modification includes a carrier 23E instead of the carrier 23A. Similar to the carrier 23 of the above embodiment, the carrier 23E has a substantially rectangular parallelepiped appearance and includes a mounting surface 23a and a bottom surface 23b. The optical semiconductor chip 22 is mounted on the mounting surface 23a. The bottom surface 23b faces the first surface 11. The material of the carrier 23E is the same as that of the carrier 23 of the above embodiment.

As shown in FIG. 19, the bottom surface 23b of the carrier 23E includes, in addition to the first contact surface 23ba and the second contact surface 23bb, a third contact surface 23bd that the first adhesive 40 contacts. As viewed from the normal direction of the bottom surface 23b, the first contact surface 23ba is positioned between the second contact surface 23bb and the third contact surface 23bd. In other words, the third contact surface 23bd is positioned outward relative to the first contact surface 23ba and on the opposite side of the first contact surface 23ba relative to the second contact surface 23bb. The third contact surface 23bd is a flat surface similarly to the first contact surface 23ba and the second contact surface 23bb. The distance D4 between the third contact surface 23bd and the first surface 11 is larger than the distance D1 between the first contact surface 23ba and the first surface 11. In other words, the third contact surface 23bd is recessed in the direction toward the mounting surface 23a relative to the first contact surface 23ba. That is, the third contact surface 23bd is positioned closer to the mounting surface 23a relative to the virtual plane including the first contact surface 23ba. Therefore, a step 23i is formed between the first contact surface 23ba and the third contact surface 23bd. The surface of the step 23i is either perpendicular to or inclined to the bottom surface 23b. The difference between the distance D4 and the distance D1 (D4−D1), that is, the height of the step 23i, is, for example, 0.01 mm or more and 0.05 mm or less.

In this modification as well, the distance D2 between the second contact surface 23bb and the first surface 11 is smaller than the distance D1 between the first contact surface 23ba and the first surface 11. Therefore, the first adhesive 40 is prevented from spreading to the second contact surface 23bb. Additionally, in this modification, the distance D4 between the third contact surface 23bd and the first surface 11 is greater than the distance D1 between the first contact surface 23ba and the first surface 11. In this case, the first adhesive 40 is further dammed by the step 23i to prevent the first adhesive 40 from spreading to the second contact surface 23bb more effectively. Therefore, according to this modification, it is more effectively possible to avoid the mixing of the first adhesive 40 and the second adhesive 50 on or near the bottom surface 23b to prevent the curing of the first adhesive 40 on or near the bottom surface 23b from being hindered by the second adhesive 50. Furthermore, it is more effectively possible to prevent the first adhesive 40 from entering between the second adhesive 50 and the bottom surface 23b to increase the area of the second contact surface 23bb, so that heat dissipation is improved even more.

The optical module and the method for manufacturing the optical module according to the present disclosure are not limited to the above-described embodiment and modifications and various other modifications can be made. For example, the disposition of the first adhesive 40 and the second adhesive 50 is not limited to the above-described embodiment and modifications. In the above-described embodiment and modifications, the optical semiconductor element 20 in which the optical semiconductor chip 22 is mounted on the carrier 23 is given as an example. The carrier 23 may be omitted, and the optical semiconductor element 20 may be configured only by the optical semiconductor chip 22. The optical semiconductor chip 22 is not limited to the semiconductor optical amplifier (SOA) and may be another optical semiconductor chip such as a semiconductor laser. The optical circuit element 30 is not limited to the silicon photonics chip and may be another optical circuit element such as an optical waveguide substrate.

Additionally, the third modification, the fourth modification, and the fifth modification illustrate cases where the substrate 10B with the groove 12 is used. Not limited to this example, the substrate 10A of the embodiment (see FIG. 1) may also be used in the third modification, the fourth modification, and the fifth modification.

What is claimed is:

1. An optical module comprising:
a base material having a first surface;
an optical semiconductor element that has a first optical port for light incidence, light emission, or light incidence and emission in a side surface thereof and is provided on the first surface;
an optical circuit element that has a second optical port for light incidence, light emission, or light incidence and emission in a side surface thereof and is disposed alongside the optical semiconductor element on the first surface, the second optical port facing the first optical port and being optically coupled to the first optical port;
a first adhesive that mainly includes a UV curable material and is disposed between the optical semiconductor element and the first surface to fix the optical semiconductor element to the first surface, the first adhesive having a first thermal conductivity; and
a second adhesive that mainly includes a thermosetting material, has a second thermal conductivity higher than the first thermal conductivity, and is disposed between the optical semiconductor element and the first surface to fix the optical semiconductor element to the first surface.

2. The optical module according to claim 1,
wherein the optical semiconductor element includes:
an optical semiconductor chip having the first optical port; and
a carrier on which the optical semiconductor chip mounted and fixed to the first surface by the first adhesive and the second adhesive.

3. The optical module according to claim 1,
wherein the UV curable material is a UV curable resin.

4. The optical module according to claim 1,
wherein the thermosetting material is sintered silver.

5. The optical module according to claim 1,
wherein the thermosetting material is epoxy-containing sintered silver.

6. The optical module according to claim 1,
wherein the first adhesive and the second adhesive are spaced apart from each other on the first surface.

7. The optical module according to claim 1,
wherein the base material has a recessed portion formed between the first adhesive and the second adhesive when viewed from a normal direction to the first surface.

8. The optical module according to claim 1, further comprising:
a third adhesive that mainly includes a UV curable material having a higher curing speed than the UV curable material of the first adhesive and is disposed between the first optical port and the second optical port.

9. The optical module according to claim 1,
wherein a contact area between the second adhesive and the optical semiconductor element is larger than a contact area between the first adhesive and the optical semiconductor element.

10. The optical module according to claim 1,
wherein the first adhesive is provided on a plurality of regions, between which the second adhesive is interposed, on the first surface.

11. The optical module according to claim 10,
wherein the plurality of regions are disposed so as to be line-symmetric with respect to an axis line along the first surface.

12. The optical module according to claim 1,
wherein the optical semiconductor element has a bottom surface facing the first surface, and
wherein the first adhesive and the second adhesive are spaced apart from each other on the bottom surface of the optical semiconductor element.

13. The optical module according to claim 2,
wherein the carrier has a bottom surface facing the first surface,
wherein the bottom surface includes a first contact surface that the first adhesive contacts and a second contact surface that the second adhesive contacts, and
wherein a distance between the second contact surface and the first surface is smaller than a distance between the first contact surface and the first surface.

14. The optical module according to claim 13,
wherein the bottom surface further includes a third contact surface that the first adhesive contacts,
wherein, as viewed from a normal direction of the bottom surface, the first contact surface is positioned between the second contact surface and the third contact surface, and
wherein a distance between the third contact surface and the first surface is smaller than a distance between the first contact surface and the first surface.

15. The optical module according to claim 13,
wherein the bottom surface further includes a third contact surface that the first adhesive contacts,
wherein, as viewed from a normal direction of the bottom surface, the first contact surface is positioned between the second contact surface and the third contact surface, and
wherein a distance between the third contact surface and the first surface is larger than a distance between the first contact surface and the first surface.

16. A method for manufacturing an optical module, the method comprising:
disposing, on a first surface of a base material, an optical circuit element having a second optical port for light incidence, light emission, or light incidence and emission in a side surface thereof, a first adhesive mainly including a UV curing material and having a first thermal conductivity, and a second adhesive that mainly includes a thermosetting material and has a second thermal conductivity higher than the first thermal conductivity;
disposing an optical semiconductor element having a first optical port for light incidence, light emission, or light incidence and emission in a side surface thereof such that the first optical port is optically coupled to the second optical port while bringing the optical semiconductor element into contact with the first adhesive and the second adhesive;
curing the first adhesive using irradiation with ultraviolet light while maintaining the optical semiconductor element at a position adjusted for optical coupling; and
curing the second adhesive using heating in a state in which the first adhesive is already cured.
